(19) United States
(12) Patent Application Publication
(10) Pub. No.: US 2024/0049600 A1
(43) Pub. Date: Feb. 8, 2024

(54) PIEZOELECTRIC ELECTRODES, UNITIZED REGENERATIVE FUEL CELL HAVING THE PIEZOELECTRIC ELECTRODES AND METHOD OF FABRICATING THEREOF

(71) Applicant: L&T TECHNOLOGY SERVICES LIMITED, Chennai (IN)

(72) Inventor: Indu PANDEY, Nagar (IN)

(21) Appl. No.: 18/081,536

(22) Filed: Dec. 14, 2022

(30) Foreign Application Priority Data
Aug. 8, 2022 (IN) 202241045113

(51) Int. Cl. H10N 30/057; H10N 30/092

(52) U.S. Cl. CPC H10N 30/057; H10N 30/092

(57) ABSTRACT

The present disclosure relates to a piezoelectric anode. a piezoelectric cathode, a unitized regenerative fuel cell comprising the piezoelectric anode and the piezoelectric cathode, and a method of fabricating thereof. The piezoelectric anode comprises metal oxide nanoparticles deposited over zero-dimensional (0D) material modified silica, a composite comprising carbon nanofibers and a zero-dimensional (0D) material, and an anode electro catalyst composition comprising alkali metal halide nanoparticles (NPs) and a polysaccharide. The piezoelectric cathode comprising metal-impregnated cellulose modified silica and a cathode electrocatalyst composition comprising calcium peroxide polymer(s).

### CROSS-REFERENCE TO RELATED APPLICATIONS

The present application claims priority to Indian Application No. 202241045113 filed with the Intellectual Property Office of India on Aug. 8, 2022 and entitled “PIEZOELECTRIC ELECTRODES, UNITIZED REGENERATIVE FUEL CELL HAVING THE PIEZOELECTRIC ELECTRODES AND METHOD OF FABRICATING THEREOF,” which is incorporated herein by reference in their entirety for all purposes.

### TECHNICAL FIELD

The present disclosure generally relates to the field of electrochemical cells and in particular it relates to piezoelectric electrodes for unitized regenerative fuel cell. More particularly, the present invention relates to a piezoelectric anode and a piezoelectric cathode, a unitized regenerative fuel cell comprising the piezoelectric anode and the piezoelectric cathode, and a method of fabricating thereof.

### BACKGROUND

Unitized regenerative fuel cells (URFCs) such as unitized regenerative hydrogen fuel cells generate hydrogen fuel from electrolysis or photolysis of water which is most commonly aqueous based catalytic hydrogen production by electrolytes. The use of aqueous electrolytes suffers from inefficiency and high-cost mainly due to freezing when temperature is low, bubbling, high pressure pumping, corrosion, and catalytic poisoning. There have been URFCs that take air as an oxygen source which cause contamination in electrolytes by other polarized gas such as CO2. Therefore, there is a need in the art for URFCs that can address one or more shortcomings of the prior art. Extracting hydrogen and oxygen fuel from air that is gas phase water (water vapor) may overcome one or more shortcomings of the prior art.

### SUMMARY OF THE DISCLOSURE

Accordingly, the disclosure herein provides a piezoelectric anode, a piezoelectric cathode, a unitized regenerative fuel cell comprising the piezoelectric anode and the piezoelectric cathode, and a method of fabricating thereof that may achieve one or more advantages over the known electrodes, URFCs and/or methods.

In an aspect, the present disclosure provides a piezoelectric anode comprising metal oxide nanoparticles deposited over zero-dimensional (0D) material modified silica, a composite comprising carbon nanofibers and a zero-dimensional (0D) material, and an anode electro catalyst composition comprising alkali metal halide nanoparticles (NPs) and a polysaccharide.

In another aspect, the present disclosure provides a piezoelectric cathode comprising metal-impregnated cellulose modified silica and a cathode electrocatalyst composition comprising calcium peroxide polymer(s).

In yet another aspect, the present disclosure provides a unitized regenerative fuel cell comprising the piezoelectric anode and the piezoelectric cathode as described herein.

In a further aspect, the present disclosure provides a method of fabricating a piezoelectric anode, the method comprising:
(i) preparing zero-dimensional (0D) material modified silica;
(ii) depositing metal oxide nanoparticles over the zero-dimensional (0D) material modified silica;
(iii) casting a composite comprising carbon nanofibers and a zero-dimensional (0D) material on the deposited oxide nanoparticles over the zero-dimensional (0D) material modified silica; and
(iv) coating an anode electro catalyst composition comprising alkali metal halide nanoparticles and a polysaccharide to the provide the piezoelectric anode.

In yet another aspect, the present disclosure provides a method of fabricating a piezoelectric cathode, comprising preparing metal-impregnated cellulose modified silica; and depositing a cathode electrocatalyst composition comprising calcium peroxide polymers on the metal-impregnated cellulose modified silica.

### BRIEF DESCRIPTION OF THE DRAWINGS

The features of the present disclosure will become fully apparent from the following description taken in conjunction with the accompanying figures. With the understanding that the figures depict only several embodiments in accordance with the disclosure and are not to be considered limiting of its scope, the disclosure will be described further through use of the accompanying figures:

FIG. 1 illustrates percentage of water uptake of piezoelectric anode from atmosphere at room temperature (25° C.).

FIG. 2 illustrates URFC system (100) in accordance with an embodiment.

FIG. 3 illustrates proposed working mechanism of the URFC in accordance with an embodiment.

FIG. 4 illustrates optimized URFC performance in both FC (fuel cell) and EC (electrochemical cell) modes.

### DETAILED DESCRIPTION

Before the methods of the present disclosure are described in greater detail, it is to be understood that the methods are not limited to particular embodiments described, as such may, of course, vary. It is also to be understood that the terminology used herein is for the purpose of describing particular embodiments only, and is not intended to be limiting, since the scope of the methods will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the methods. The upper and lower limits of these smaller ranges may independently be included in the smaller ranges and are also encompassed within the methods, subject to any specifically excluded limit in the stated range. Where the stated range includes one or both of the limits, ranges excluding either or both of those included limits are also included in the methods.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by those of ordinary skill in the art to which the disclosure belongs. Although any methods and materials similar or equivalent to those described herein can be used in the practice or testing of the present disclosure, preferred methods and materials are described. For the purposes of the present disclosure, the following terms are defined below.

The articles “a” and “an” are used herein to refer to one or to more than one (i.e., to at least one) of the grammatical object of the article. By way of example, “an element” means one element or more than one element.

As used herein, the term “comprises” or “comprising” is generally used in the sense of include, that is to say permitting the presence of one or more features or components.

As used herein, the term “alkali metal halide” refers to a halide of a metal selected from group 1 of the periodic table. The alkali metal halide can be a single alkali metal halide or a mixture of different alkali metal halides. The alkali metal refers to lithium, sodium, potassium, rubidium, and cesium. The term “halide” refers to fluoride, chloride, bromide, and iodide. Examples of alkali metal halide include, but are not limited to, LiCl, NaCl, KCl, RbCl, and CsCl.

As used herein, the term “polysaccharide” refers to natural polysaccharide, synthetic polysaccharide, and polysaccharide derivates. Examples of polysaccharide include, but are not limited to, alginate, starch, dextran, chitosan, chitosan derivatives, cellulose and/or non-cellulose derivatives.

Disclosed are a piezoelectric anode, a piezoelectric cathode, a unitized regenerative fuel cell comprising the piezoelectric anode and the piezoelectric cathode, and a method of fabricating them.

In an embodiment, the present disclosure provides a piezoelectric anode comprising metal oxide nanoparticles deposited over zero-dimensional (0D) material modified silica, a composite comprising carbon nanofibers and a zero-dimensional (0D) material, and an anode electro catalyst composition comprising alkali metal halide nanoparticles (NPs) and a polysaccharide.

In certain embodiments, the piezoelectric anode comprises:
i. about 10-30 wt. % of metal oxide nanoparticles;
ii. about 30-70 wt. % of silica;
iii. about 10-20 wt. % of composite comprising carbon nanofibers and a zero-dimensional (0D) material; and
iv. about 10-20 wt. % of anode electro catalyst composition.

In certain embodiments, the piezoelectric anode comprises:
i. about 20 wt. % of metal oxide nanoparticles;
ii. about 50 wt. % of silica;
iii. about 15 wt. % of composite comprising carbon nanofibers and a zero-dimensional (0D) material; and
iv. about 15 wt. % of anode electro catalyst composition.

Metal oxide nanoparticles include, but are not limited to, titanium oxide, zinc oxide, quartz, zirconia, or any combination thereof or any metal oxide nanoparticles suitable for the purposes of the present disclosure may be used. In certain embodiments, the metal oxide nanoparticles comprise titanium oxide, zinc oxide or combination of titanium oxide and zinc oxide. In some instances, the metal oxide nanoparticles comprise combination of titanium oxide and zinc oxide. In certain embodiments, the metal oxide nanoparticles have a size of about 40-200 nm, or about 120 nm, or about 100 nm, or about 100 nm or about 50-70 nm.

In certain embodiments, the piezoelectric anode comprises zero-dimensional (0D) material modified silica in partially reduced form or fully reduced form. In certain embodiments, the piezoelectric anode comprises partially reduced fullerene-C60 modified silica or fully reduced fullerene-C60 modified silica.

In certain embodiments, the piezoelectric anode comprises 1:1 composite of carbon nanofibers and a zero-dimensional (0D).

Zero-dimensional (0D) material as described in this disclosure includes, but not limited to, one or more of fullerenes, carbon quantum dots (CQDs), graphene quantum dots (GQDs), inorganic quantum dots (QDs), magnetic nanoparticles (MNPs), noble metal nanoparticles, upconversion nanoparticles (UCNPs) and polymer dots (Pdots). In certain embodiments, Zero-dimensional (0D) material is fullerene or carbon dots.

In certain embodiments, the carbon nanofibers have a size of about 50-100 nm, or about 55-80 nm, or about 70 nm, or about 80 nm, or about 100 nm.

In certain embodiments, the piezoelectric anode comprises carbon nanofibers and carbon dots in a ratio of about 1:1.

In certain embodiments, the electro catalyst composition of the piezoelectric anode comprises about 60 wt % of alkali metal halide nanoparticles (NPs) and about 40 wt % polysaccharide. In certain embodiments, the alkali metal halide nanoparticles include, but are not limited to, alkali metal chloride nanoparticles. The alkali metal chloride includes, but not limited to, LiCI, NaCl, KCl, RbCl and CsCl. In some instances, the alkali metal chloride is NaCl. The polysaccharide includes, but not limited to, alginate. In some instances, the anode electro catalyst composition of the piezoelectric anode comprises NaCl nanoparticles (NPs) and alginate.

In certain embodiments, the piezoelectric anode of the present disclosure comprises reduced fullerene modified silica, nanoparticles of TiO2 and ZnO2, a composite comprising carbon nanofibers and carbon dots, and an anode electro catalyst composition comprising NaCl nanoparticles and alginate. In some instances, the composite of the piezoelectric anode comprises carbon nanofibers and carbon dots in a ratio of about 1:1.

In certain embodiments, the anode electrocatalyst as disclosed herein is fluorescent and hygroscopic.

In certain embodiments, the present disclosure provides a piezoelectric cathode comprising metal-impregnated cellulose and a cathode electrocatalyst composition comprising calcium peroxide polymer(s).

The metal in the metal-impregnated cellulose is selected from the group comprising iron, nickel, molybdenum, zirconate, titanate, quartz, Rochelle salt and any combination thereof. The amount of metal in the metal-impregnated cellulose is from 20 wt. % to 30 wt. %. The cellulose is selected from the group comprising cotton nanocellulose film of about 20 mm thickness.

In certain embodiments, the piezoelectric cathode as described herein has self-generating oxygen capability as shown below:

CaO₂+2H₂O [symbol] [symbol] (OH)₂+H₂O₂

2H₂O₂ [symbol] 2H₂O+O₂

The cathode surface of URFCs can be consider as a small cloud, with one side open to air and the other sealed. Water molecules in the air constantly bump into the open surface, creating more charges than on the other one. The charge difference eventually will build up electric field or potential difference, which will drive the electric current output.

In certain embodiments, the present disclosure provides a unitized regenerative fuel cell (URFC) comprising a piezoelectric anode and a piezoelectric cathode as described herein. In certain embodiments, the unitized regenerative fuel cell comprises:
i. a piezoelectric anode comprising metal oxide nanoparticles deposited over zero-dimensional (0D) material modified silica, a composite comprising carbon nanofibers and a zero-dimensional (0D) material, and an anode electro catalyst composition comprising alkali metal halide nanoparticles (NPs) and a polysaccharide; and
ii. a piezoelectric cathode comprising metal-impregnated cellulose modified silica and a cathode electrocatalyst composition comprising calcium peroxide polymer(s);
   wherein the metal oxide nanoparticles, zero-dimensional (0D) material modified silica, composite comprising carbon nanofibers and zero-dimensional (0D) material, and anode electro catalyst composition comprising alkali metal halide nanoparticles (NPs) and a polysaccharide are same as defined herein above.

In the unitized regenerative fuel cell as disclosed herein, when hygroscopic fluorescence electrocatalyst adsorbs moisture, a strain is developed between the anode and the cathode thereby producing an electricity which splits the moisture into H2 and O2 while the calcium peroxide polymer(s) coated on the cathode release and store oxygen in presence of moisture.

In certain embodiments, the URFC as disclosed herein is air breathing fluorescent self-powered unitized regenerative hydrogen fuel.

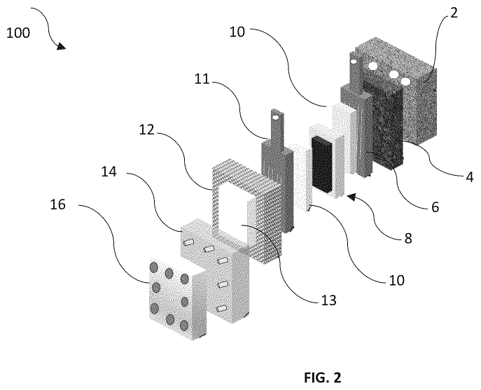

In certain embodiments, the structure of the URFC is shown in FIG. 2. As shown in FIG. 2, the URFC (100) comprises a membrane electrode assembly (MEA) (8) where both piezoelectric anode, piezoelectric cathode (with catalyst loading 2.5 mg cm⁻²) and Nafion ionomers (Fuel Cells Etc, USA) are hot pressed, one or more gas diffusion layers (GDL) (10), one or more flow field plates (6, 11, 13), a transparent end plate (14), a splint (16), insulation spacer (4), one or more end plates (2), and optionally, one or more insulated rings.

In certain embodiments, polycarbonate plate is used as a transparent end plate.

In certain embodiments, the active area of the MEA is 5 cm×5 cm, with 2.5 mg cm⁻² electrocatalyst cathode and anode.

In certain embodiments, GDL in oxygen side is Titania and Platinum nanoparticles screen to resist the corrosion issue during EC (Electrolytic cell) mode. The GDL in hydrogen side is exfoliated graphene paper.

In certain embodiments, the open area of a single layer of titania and platinum nanoparticles screen is 65%, and the titania and platinum nanoparticles screen are doubled up to be used as GDL in oxygen side.

In certain embodiments, the porosity of carbon paper used in hydrogen electrode side is 80%. Serpentine flow fields (2 mm channel width, 2 mm rib width, 2 mm channel depth and 48 mm channel length) are used for both sides and made of titanium.

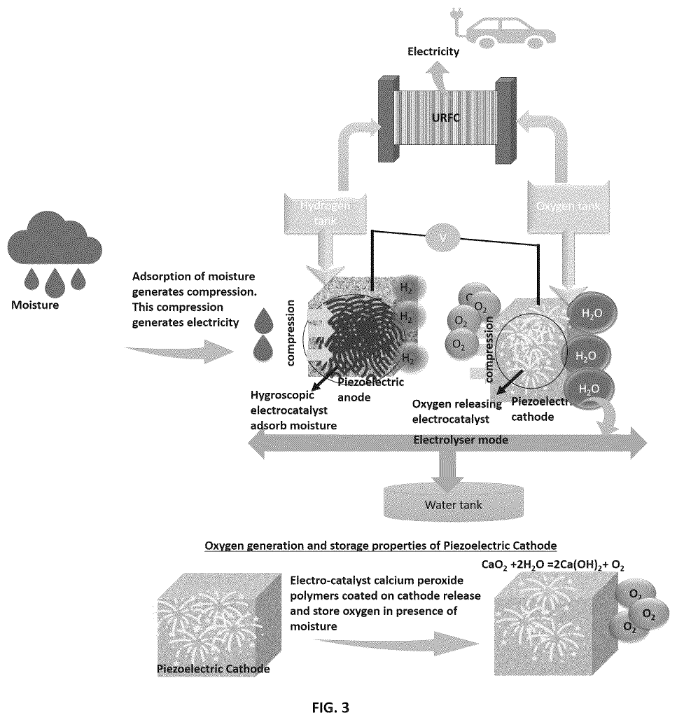

FIG. 3 illustrates the proposed working mechanism of the URFC as provided herein. As shown in FIG. 3, piezoelectric electrodes (anode and cathode) are integrated to develop air breathing URFCs. When moisture adsorbs by hygroscopic fluorescence electrocatalyst, strain is developed between two electrodes which produces electricity. The electricity produces via piezoelectric effect tigers the moisture to split into H₂ and O₂. At cathode, electro-catalyst composition of calcium peroxide polymers coated on iron-nickel doped cellulosic nanofibers silica. It has self-recharging process, shows 0.4 to 0.62 V for 25 hours. In URFCs, energy is generated in the device due to a moisture gradient that forms within the electro-catalyst film when it is exposed to the humidity naturally present in air. The smaller electrode on the top is key, as it leaves one side exposed to the humid air, allowing the moisture gradient to develop. Cathode surface of URFCs can be consider as a small cloud, with one side open to air and the other sealed. Water molecules in the air constantly bump into the open surface, creating more charges than on the other one. The charge difference eventually will build up electric field or potential difference, which will drive the electric current output. Anode surface of URFCs has self-oxygen storage and generating properties. These properties increase the current efficiency of whole URFCs with enhancement in life cycles as well.

The present disclosure also provides a method for fabrication of piezoelectric electrodes.

In certain embodiments, the present disclosure provides a method of fabricating a piezoelectric anode. The method comprises:
(i) preparing zero-dimensional (0D) material modified silica;
(ii) depositing metal oxide nanoparticles over the zero-dimensional (0D) material modified silica;
(iii)casting a composite comprising carbon nanofibers and a zero-dimensional (0D) material on the deposited oxide nanoparticles over the zero-dimensional (0D) material modified silica; and
(iv) coating an anode electro catalyst composition comprising alkali metal halide nanoparticles and a polysaccharide to provide the piezoelectric anode.

In certain embodiments of a method of fabricating the piezoelectric anode, zero-dimensional (0D) material, zero-dimensional (0D) material modified silica, metal oxide nanoparticles, carbon nanofibers, alkali metal halide nanoparticles and polysaccharide are same as described above.

The zero-dimensional (0D) material modified silica may be prepared by any method known in the art. In certain embodiments, the preparation of zero-dimensional (0D) material modified silica comprises the steps of preparing a suspension of zero-dimensional (0D) material in a solvent such as 1-chloronaphthalene and then casting the suspension on silica. Then it is subjected to reduction to obtain partially or fully reduced zero-dimensional (0D) material modified silica. In certain embodiments, the reduction is an electrochemical reduction or a catalytic hydrogenation. In some instances, the reduction is an electrochemical reduction. In certain embodiments, the electrochemical reduction is conducted in sodium hydroxide solution. The concentration of sodium hydroxide solution is about 0.05-10 M, or about 0.1-10 M or about 0.5-5 M or about 0.5-3 M or about 0.5-1.5. In certain embodiments, the concentration of sodium hydroxide solution is about 0.5-1.5 M or about 0.5-1 M.

Then metal oxide nanoparticles are deposited over the zero-dimensional (0D) material modified silica. The metal oxide nanoparticles may be deposited over the zero-dimensional (0D) material modified silica by any method known in the art. Suitable methods for depositing may include, but are not limited to, electrochemical deposition, atomic layer deposition, cathodic arc deposition, DC (Direct Current)/RF (Radio frequency) magnetron sputtering, arc spray metallization, plasma-enhanced chemical vapor deposition (PECVD), chemical vapor deposition (CVD), metal-organic vapor phase epitaxy, molecular beam epitaxy, physical vapor deposition, pulsed laser deposition, sputtering, or any combination thereof. In certain embodiments, the metal oxide nanoparticles are deposited over the zero-dimensional (0D) material modified silica by electrochemical deposition. In some instances, the zero-dimensional (0D) material modified silica is placed in a cell containing an oxidizing agent and one or more precursors of metal oxide nanoparticles to electrodeposit the metal oxide nanoparticles over the zero-dimensional (0D) material modified silica. In certain embodiments, the oxidizing agent is peroxide, or any suitable oxidizing agent may be used. In some instances, the oxidizing agent is 0.5 M peroxide. In certain embodiments, metal oxide nanoparticles are electrodeposited in the potential range of about −0.1 and 1.5V at the scan rate 5 m Vs⁻¹. The thickness of the metal oxide nanoparticles can be controlled by potential cycles and precursor concentration.

After the deposition of metal oxide nanoparticles, a composite comprising carbon nanofibers and a zero-dimensional (0D) material is casted. In certain embodiments, 1:1 ratio of carbon nanofibers and zero-dimensional (0D) material composite is drop casted.

Thereafter, an anode electro catalyst composition comprising alkali metal halide nanoparticles and a polysaccharide is coated onto to casted material to provide the piezoelectric anode. The coating can be done by any method known in the art, for example, spin coating or any method known in the art such as spin coating, spray coating, drop-casting, electrochemical deposition, atomic layer deposition, cathodic arc deposition, DC (Direct Current)/RF (Radio frequency) magnetron sputtering, arc spray metallization, plasma-enhanced chemical vapor deposition (PECVD), chemical vapor deposition (CVD), metal- organic vapor phase epitaxy, molecular beam epitaxy, physical vapor deposition, pulsed laser deposition, and sputtering. In certain embodiments, the anode electro catalyst composition is spin coated and then dried. The anode electro catalyst composition is prepared by adding alkali metal halide nanoparticles to a solution of polysaccharide.

In certain embodiments of a method of fabricating the piezoelectric anode, the metal oxide nanoparticles are selected from the group comprising titanium oxide, zinc oxide, and any combination thereof; the zero-dimensional (0D) material comprises one or more of fullerenes, carbon quantum dots (CQDs), graphene quantum dots (GQDs), inorganic quantum dots (QDs), magnetic nanoparticles (MNPs), noble metal nanoparticles, upconversion nanoparticles (UCNPs) and polymer dots (Pdots); the alkali metal halide is an alkali metal chloride (e.g. NaCl); the composite comprises carbon nanofibers and carbon dots in a ratio of 1:1; and the polysaccharide is alginate.

Sodium NPs and alginates are the salts of linear copolymers of b-(1-4)-linked D-mannuronic acid and a-(1-4)-linked L-guluronic acid units which contain a lot of hydroxyl groups. These hydroxyl groups are responsible for strong hydrophilic nature of sodium alginate fibers.

In certain embodiments, the present disclosure provides a method of fabricating a piezoelectric cathode. The method comprises:
i. preparing metal-impregnated cellulose modified silica; and
ii. depositing a cathode electrocatalyst composition comprising calcium peroxide polymers on the metal-impregnated cellulose modified silica.

The metal-impregnated cellulose modified silica is prepared by the following steps, comprising impregnating cellulose with metal salt(s) to provide metal-impregnated cellulose; pyrolyzing the metal-impregnated cellulose to provide metal nanoparticles doped cellulosic carbon nanofibers; and loading the metal nanoparticles doped cellulosic carbon nanofibers on silica to provide metal-impregnated cellulose modified silica.

In certain embodiments of a method of fabricating the piezoelectric cathode, the pyrolysis of metal-impregnated cellulose is done at a temperature of about 300-600° C. or about 400-500° C. In some instances, the pyrolysis is done at about 400-500° C. to provide metal nanoparticles doped cellulosic carbon nanofibers. Then, the metal nanoparticles doped cellulosic carbon nanofibers are dissolved in a solvent such as DMF and then loaded on silica to provide metal-impregnated cellulose modified silica. Thereafter, a cathode electrocatalyst composition comprising calcium peroxide polymers (e.g., 5% 1 mL in 50 mL of polylactic acid) is deposited on the metal-impregnated cellulose modified silica and dried. The depositing can be done by any method known in the art, for example, spin coating or any method known in the art such as drop-casting, spin coating, spray coating, electrochemical deposition, atomic layer deposition, cathodic arc deposition, DC (Direct Current)/RF (Radio frequency) magnetron sputtering, arc spray metallization, plasma-enhanced chemical vapor deposition (PECVD), chemical vapor deposition (CVD), metal-organic vapor phase epitaxy, molecular beam epitaxy, physical vapor deposition, pulsed laser deposition, and sputtering. In certain embodiments, the cathode electrocatalyst composition is deposited by drop casting.

The present disclosure is further described with reference to the following examples, which are only illustrative in nature and should not be construed to limit the scope of the present disclosure in any manner.

### EXAMPLES

### Example 1: Development of Piezoelectric Anode

2 mg/ml standard solution of fullerene-C60 was prepared in the 1-chloronaphthalene using a sonicator. 2-3 μl (optimized amount) of this suspension was cast on Silica and dried under an infrared lamp for 45 min. The electrochemical reduction of fullerene—C₆₀ modified silica was performed in 1.0 M sodium hydroxide solution using 20 consecutive potential cycles between 0.01 V and −0.8 V at the 1 m Vs⁻¹. Now reduced-fullerene-C₆₀/silica was placed in a cell containing 0.5 M peroxide and 10 mM titanium nitrate and Zinc nitrate. Both nanoparticles were electrodeposited in the potential range between −0.1 and 1.5V at the scan rate 5 mVs⁻¹. The thickness of both nanoparticles was controlled by potential cycles and precursor concentration. After the deposition of both nanoparticles, the surface of the reduced-fullerene-C₆₀ modified silica changed from dark grey to golden brown. Carbon nanofibers and carbon dots (1:1) composite in 1 mL DMF was drop casted on anode and dried for 45° C. for 24 h.

Then an aqueous phase consisting of 0.5% w/v sodium alginate was prepared. In order to prepare an aqueous phase consisting of 0.5% w/v sodium alginate (Sigma Aldrich, India), 0.5 g of alginate powder was dissolved in deionized water at room temperature. Then, the alginate solution was maintained at 3° C for 24h to remove air bubbles. Various concentrations of the NaCl nanoparticles (NPs) (25, 50, 75, 100, 150, 200, 225, and 250 ppm) were added to the alginate solution and thoroughly mixed by continuous agitation in a magnetic stirrer to ensure complete dissolution of the polymers. Then, the treated solution was spin coated at 200 rpm and then dried in an oven(70° C.) for 40 min.

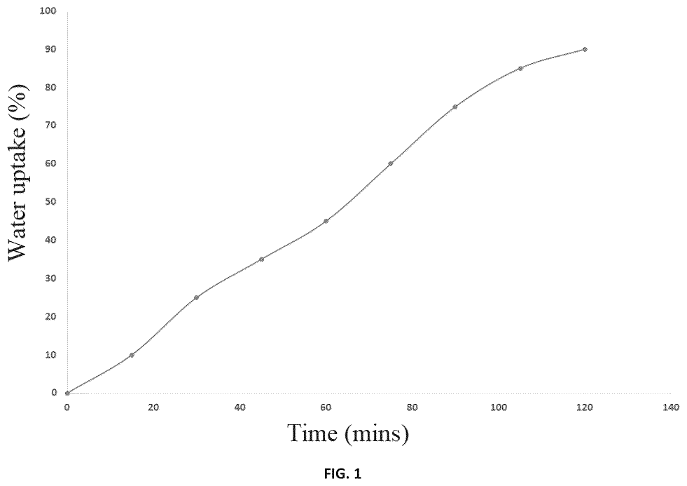

Water uptake of anode was carried out at room temperature (25° C.) from atmosphere for 1-2 hrs. The results were presented in FIG. 1. It was found after 30 secs exposure to the environment, anode absorbed 10% of water at 15 minutes, but 90% of mass gained after 120 min.

The reaction at piezoelectric anode:

EC mode: H₂O(adsorb moisture) [symbol] H₂+O₂

FC mode: H₂ [symbol] 2H⁺+2e⁻

### Example 2: Fabrication of Cathode

### Metal Impregnation in Cellulose:

10 g of cellulose sample in 200 cm³ of a 1.0 mol dm³ aqueous metal solution (iron nitrate

and nickel molybdate (metal salts completely dissolved) and mixing the suspension on a magnetic stirrer for 72 h at room temperature. The samples were subsequently filtered and washed with 50 cm³ of deionized water to remove ions not chemically bound to the cellulose. Finally, the as prepared impregnated samples were dried at 110° C. for 48 h. The sample was pyrolyzed at 400-500° C. and metal nanoparticles (NPs) doped cellulosic carbon nanofibers formed. The resulted iron-nickel molybdenum NPs doped cellulosic carbon nanofibers dissolved in DMF by ultrasonication and loaded on silica. Then, an electrocatalyst calcium peroxide polymers (5% 1 mL in 50 mL of Polylactic acid) was deposited by drop casting on iron-nickel molybdenum NPs doped cellulosic carbon nanofibers modified silica. The resultant cathode was dried at room temperature for 48 h, and 24 h in vacuum.

The fabricated cathode has oxygen storage and generation properties at ambient temperature range (20-45° C.) (discussed below).

EC mode (piezoelectric mode): H₂O(adsorb moisture) [symbol] H₂+O₂

FC piezoelectric mode: O₂+2H+2e⁻ [symbol] H₂O

The cathode has self-recharging process, shows 0.4 to 0.62 V for 25 hours.

### Example 3: URFC Assembly

The structure of the URFC used in this example is shown in FIG. 2. The cell consisted of a membrane electrode assembly (MEA) (8) where both anode, cathode (with catalyst loading 2.5 mg cm⁻²) and Nafion ionomers were (Fuel Cells Etc., USA) were hot pressed, gas diffusion layers (GDL) (10), flow filed plates (6, 11, 13), a polycarbonate plate as a transparent end plate (14), insulation spacer (4), and a splint (16). The active area of the MEA was 5 cm×5 cm, with 2.5 mg cm⁻² electrocatalyst cathode and anode. GDL in oxygen side was Titania and Platinum nanoparticles screen to resist the corrosion issue during EC mode, and the GDL in hydrogen side was exfoliated graphene paper. The open area of a single-layer of titania and Platinum nanoparticles screen was 65%, and the Titania and Platinum nanoparticles screen was doubled up to be used as GDL in oxygen side. The porosity of carbon paper used in hydrogen electrode side was 80%. Serpentine flow fields (2 mm channel width, 2 mm rib width, 2 mm channel depth and 48 mm channel length) were used for both sides and made of titanium.

In this example, the clamping torque of the cell was 3.0 N·m, and the cell temperature was 45° C. Cell voltage during water electrolysis reaction has a little change when water flow rate in range of 1 to 10 ml min⁻¹, and most of the voltage variation is caused by temperature. The temperature of supplied water is consistent with the cell. Thus, adequate water supply (10 ml min⁻¹) was used in this work. The oxygen and hydrogen flow rates for FC mode were 100 and 200 ml min⁻¹ (2 times stoichiometric flow rate at 500 mAcm⁻²), respectively. The moment, current transition to FC mode, was defined as 0 s. The cell firstly ran EC mode for 300 s, from −1600 s to −1300 s, and then EC mode and water supply were stopped, and gas purge was started. The nitrogen flow rates for oxygen and hydrogen side were 300 and 100 ml min⁻¹, respectively. In EC mode, the moisture adsorbed and supplied in oxygen electrode side. To quickly remove the residual water at the end of EC mode was done on electrode only, the purge gas flow rate and purging time in oxygen side was always higher than that in hydrogen side. After 1250 s, gas purge was stopped, and the cell was kept at rest for 90 s to regulate oxygen and hydrogen flow rates. To ensure oxygen and hydrogen reached channels when FC mode started up, the hydrogen and oxygen supplies were started 30 s before current transition. At 0 s, current was switched to negative value, operating FC mode.

FIG. 3 illustrates proposed working mechanism of the URFC.

URFC performance was evaluated using the round-trip efficiency between FC and EC modes. The round-trip efficiency was calculated by dividing the cell voltage in FC mode by that observed in EC mode at constant current density of 500 mAcm⁻². To characterize the resistance in the FC and EC modes of the URFC, electrochemical impedance spectra were obtained at −500 (FC mode) and 500 mAcm⁻² (EC mode) with frequencies ranging from 100 mHz to 100 kHz.

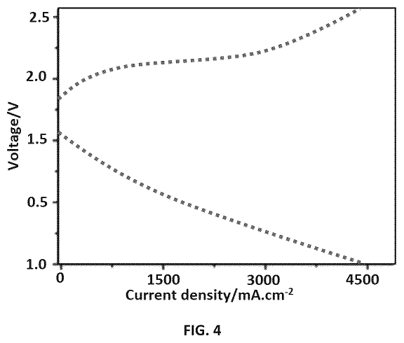

FIG. 4 shows the optimal URFC performance operated in both FC and EC modes. The operational parameters are tabulated in Table 1. The URFC exhibited a high initial round-trip efficiency of 55% at 500 mAcm⁻² (Single Cell=FC mode: 0.82V and EC mode: 1.35V).

TABLE 1
Operational Parameter of URFC (10 cells active area 5 × 5 cm²)

| | | Electrolytic | Fuel |
|---|---|---|---|
| S. No. | Parameters | cell mode | cell mode |
| 1. | Nominal Voltage (V) | 10.1 | 3.5 |
| 2. | Nominal Current (A) | 120 | — |
| 3. | Nominal Electric Power (W) | 1230 | 500 |
| 4. | Operating Temperature (° C.) | 60 | — |
| 5. | Operating Pressure of Hydrogen (bar) | — | 3.2 |
| 6. | Operating Pressure of Oxygen (bar) | — | 2.8 |

### Advantages:

First time fully gas phase unitized regenerative fuel cells are invented by the present inventors.
The present developed metal free-hydrogen storable polymeric nanocomposite anode based URFCs which is fully moisture assisted energy storage system.
The URFCs has its own oxygen generating cathode in presence of moisture/water vapour. Thus, water flooding issue in URFCs are also solving here by consuming water in generating oxygen. This feature also applicable in space where hydrogen fuel cells are failed since all reactants are gases so phase change issue in space is solved by this URFCs.
Cathode surface of URFC has self-oxygen storage and generating properties. This property increases current efficiency of whole URFCs with enhancement in life cycles.
The total cost ownership analysis shows that this technology is not only cheaper and unique but also reduce the 95% cost of electric vehicles (EVs) as well as self-powered devices such as grids, space crafts and aircrafts.

Although the foregoing disclosure has been described in some detail by way of illustration and examples for purposes of clarity of understanding, it is readily apparent to those of ordinary skill in the art in light of the teachings of this disclosure that certain changes and modifications may be made thereto without departing from the spirit or scope of the appended claims.

Accordingly, the preceding merely illustrates the principles of the disclosure. It will be appreciated that those skilled in the art will be able to devise various arrangements which, although not explicitly described or shown herein, embody the principles of the disclosure and are included within its spirit and scope. Furthermore, all examples and conditional language recited herein are principally intended to aid the reader in understanding the principles of the disclosure and the concepts contributed by the inventors to furthering the art and are to be construed as being without limitation to such specifically recited examples and conditions. Moreover, all statements herein reciting principles, aspects, and embodiments of the disclosure as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present disclosure, therefore, is not intended to be limited to the exemplary embodiments shown and described herein. Rather, the scope and spirit of present disclosure is embodied by the appended claims.

We claim:

1. A piezoelectric anode comprising metal oxide nanoparticles deposited over zero-dimensional (0D) material modified silica, a composite comprising carbon nanofibers and a zero-dimensional (0D) material, and an anode electro catalyst composition comprising alkali metal halide nanoparticles (NPs) and a polysaccharide.

2. The piezoelectric anode as claimed in claim 1, wherein the metal oxide nanoparticles comprise titanium oxide, zinc oxide, quartz, zirconia, or any combination thereof.

3. The piezoelectric anode as claimed in claim 1, wherein the zero-dimensional (0D) material comprises one or more of fullerenes, carbon quantum dots (CQDs), graphene quantum dots (GQDs), inorganic quantum dots (QDs), magnetic nanoparticles (MNPs), noble metal nanoparticles, upconversion nanoparticles (UCNPs) and polymer dots (Pdots).

4. The piezoelectric anode as claimed in claim 1, wherein the alkali metal halide is an alkali metal chloride.

5. The piezoelectric anode as claimed in claim 1, wherein the composite comprises carbon nanofibers and zero-dimensional (0D) material in a ratio of about 1:1.

6. The piezoelectric anode as claimed in claim 1, wherein the polysaccharide is alginate.

7. The piezoelectric anode as claimed in claim 1, comprises reduced fullerene modified silica, nanoparticles of TiO₂ and ZnO₂, a composite comprising carbon nanofibers and carbon dots in a ratio of about 1:1, and an anode electro catalyst composition comprising NaCl nanoparticles and alginate.

8. The piezoelectric anode as claimed in claim 1, wherein the anode electrocatalyst is fluorescent and hygroscopic.

9. A piezoelectric cathode comprising metal-impregnated cellulose modified silica and a cathode electrocatalyst composition comprising calcium peroxide polymer(s).

10. The piezoelectric cathode as claimed in claim 9, wherein the metal is selected from the group comprising iron, nickel, molybdenum, zirconate, titanate, quartz, Rochelle salt and any combination thereof.

11. A unitized regenerative fuel cell comprising:
i. a piezoelectric anode as claimed in any one of claim 1; and
ii. a piezoelectric cathode comprising metal-impregnated cellulose modified silica and a cathode electrocatalyst composition comprising calcium peroxide polymer(s).

12. The unitized regenerative fuel cell as claimed in claim 11, wherein the unitized regenerative fuel cell is air breathing regenerative fuel cell.

13. The unitized regenerative fuel cell as claimed in claim 11, wherein when hygroscopic fluorescence electrocatalyst adsorbs moisture, a strain is developed between the anode and the cathode thereby producing an electricity which splits the moisture into H₂ and O₂.

14. The unitized regenerative fuel cell as claimed in claim 11, wherein the calcium peroxide polymer(s) coated on the cathode release and store oxygen in presence of moisture.

15. A method of fabricating a piezoelectric anode, the method comprising:
a) preparing zero-dimensional (0D) material modified silica;
b) depositing metal oxide nanoparticles over the zero-dimensional (0D) material modified silica;
c) casting a composite comprising carbon nanofibers and a zero-dimensional (0D) material on the deposited oxide nanoparticles over the zero-dimensional (0D) material modified silica; and
d) coating an anode electro catalyst composition comprising alkali metal halide nanoparticles and a polysaccharide to provide the piezoelectric anode.

16. The method as claimed in claim 15, wherein the metal oxide nanoparticles are selected from the group comprising titanium oxide, zinc oxide, and any combination thereof; the zero-dimensional (0D) material comprises one or more of fullerenes, carbon quantum dots (CQDs), graphene quantum dots (GQDs), inorganic quantum dots (QDs), magnetic nanoparticles (MNPs), noble metal nanoparticles, upconversion nanoparticles (UCNPs) and polymer dots (Pdots); the alkali metal halide is an alkali metal chloride; the composite comprises carbon nanofibers and carbon dots in a ratio of 1:1; and the polysaccharide is alginate.

17. A method of fabricating a piezoelectric cathode, comprising preparing metal-impregnated cellulose modified silica; and depositing a cathode electrocatalyst composition comprising calcium peroxide polymers on the metal-impregnated cellulose modified silica.
